(19) United States
(12) Patent Application Publication
(10) Pub. No.: US 2015/0015272 A1
(43) Pub. Date: Jan. 15, 2015

(54) GROUND ROD TESTING DEVICE FOR GROUND CHARACTERISTIC ANALYSIS

(71) Applicant: OMNI LPS. CO., LTD., Seoul (KR)

(72) Inventor: Young-ki Chung, Seoul (KR)

(21) Appl. No.: 14/379,663

(22) PCT Filed: Feb. 26, 2013
(86) PCT No.: PCT/KR2013/001516

§ 371 Date: Aug. 19, 2014

(30) Foreign Application Priority Data
Apr. 3, 2012 (KR) 10-2012-0034591

(51) Int. Cl. G01R 31/02

(52) U.S. Cl. CPC G01R 31/021
USPC 324/543

(57) ABSTRACT

The present invention relates to a ground rod testing device for ground characteristic analysis. The ground rod testing device according to the present invention includes: an impulse generator generating an impulse waveform; a testing chamber accommodating the ground rod in which the impulse waveform is applied and a conductive fluid; a sensor for sensing the impulse waveform output from the ground rod; and a measuring instrument for measuring the impulse waveform sensed by the sensor.

### TECHNICAL FIELD

The present invention relates to a ground rod test device and, more particularly, to a ground rod test device for analyzing ground characteristics, which prevents noise, vibration, and sparks generated when an impulse current is applied using a test chamber that accommodates a conductive liquid.

### BACKGROUND ART

In general, an impulse current generator is an apparatus for generating an artificial impulse current of 10/350 μs, that is, the first short-time lighting impulse standard waveform, for simulating a danger of the falling of a thunderbolt or a surge current attributable to a switching surge because the falling of a thunderbolt or the surge current is applied to insulating parts, such as a transformer, a breaker, and an insulator used in a power transmission and distribution system.

When a surge impedance test is performed on a ground rod, the ground rod is seated in a test chamber in order to prevent noise, vibration, and sparks generated when an impulse current is applied to the ground rod.

A conventional hemispherical test chamber, however, has a difficulty in performing a test for analyzing ground characteristics on the spot because noise, vibration, and sparks are generated due to an impulse current.

### DISCLOSURE

### Technical Problem

The present invention has been made to solve the above problems, and an object of the present invention is to provide a ground rod test device for analyzing ground characteristics, which prevents noise, vibration, and sparks generated when an impulse current is applied using a test chamber that accommodates a conductive liquid.

### Technical Solution

To achieve the above object, a ground rod test device for analyzing ground characteristics according to the present invention includes an impulse generator that generates an impulse waveform, a test chamber that accommodates a ground rod to which the impulse waveform is applied and a conductive fluid, a sensor that senses the impulse waveform output by the ground rod, and a measuring instrument that measures the impulse waveform sensed by the sensor.

The impulse generator includes first DC charging means electrically connected to an input power source for generating an impulse current, a first spark gap electrically connected between the first DC charging means and the ground rod of the test chamber and operating response to a trigger signal output by a first trigger module, a coil electrically connected between the first spark gap and a test load and controlling the wave tail part of the impulse waveform, second DC charging means electrically connected to an input power source for generating an impulse voltage, a second spark gap electrically connected between the second DC charging means and a crowbar switch module and operating in response to a trigger signal generated by a second trigger module, second charging means electrically connected between the second DC charging means and the second spark gap, a time constant control circuit electrically connected between the second spark gap and the crowbar switch module and controlling a time constant of the impulse waveform, and a control means that controls the first and the second trigger modules and the first and the second spark gaps so that the wave tail and wave front parts of the impulse waveform are formed.

The test chamber includes a support unit having the top open and a plurality of casters installed at the edges of the bottom of the support unit, a lower body inserted into and coupled to the top of the support unit, wherein first and second insertion grooves and an output that downward penetrates the lower body toward an outside wall are formed at the center of the top surface of the lower body, an upper body coupled with the top of the lower body by coupling means, wherein a through hole that penetrates the upper body up and down is formed at the center of the upper body, a pipe formed in a pillar shape and inserted into and coupled with the through hole, and a finishing unit that closes the top of the pipe, wherein a hole is formed at a center of the finishing unit, wherein the ground rod is seated in an accommodation space formed by the coupling of the lower body, the upper body, and the pipe, and the accommodation space is filled with the conductive fluid.

The outer circumferential surface of the pipe is surrounded by insulating coating.

The ground rod test device further includes a valve installed in the outlet in order to externally discharge the conductive fluid of the accommodation space.

Gaskets for preventing the conductive fluid from leaking are inserted into and installed at the first and the second insertion grooves.

Buffer materials for reducing vibration generated when the impulse current is applied to the ground rod are attached to an inner surface of the support unit.

### Advantageous Effects

Accordingly, the ground rod test device for analyzing ground characteristics according to the present invention can safely perform a ground characteristic analysis on the spot because it prevents noise, vibration, and sparks, generated due to an impulse current when the impulse current is applied, using the test chamber that accommodates a conductive liquid.

### DESCRIPTION OF DRAWINGS

FIG. 1 is a circuit diagram illustrating a ground rod test device for analyzing ground characteristics according to the present invention; and

FIG. 2 is a side view illustrating the ground rod test device of FIG. 1.

### MODE FOR INVENTION

Hereinafter, the present invention is described in detail with reference to the accompanying drawings.

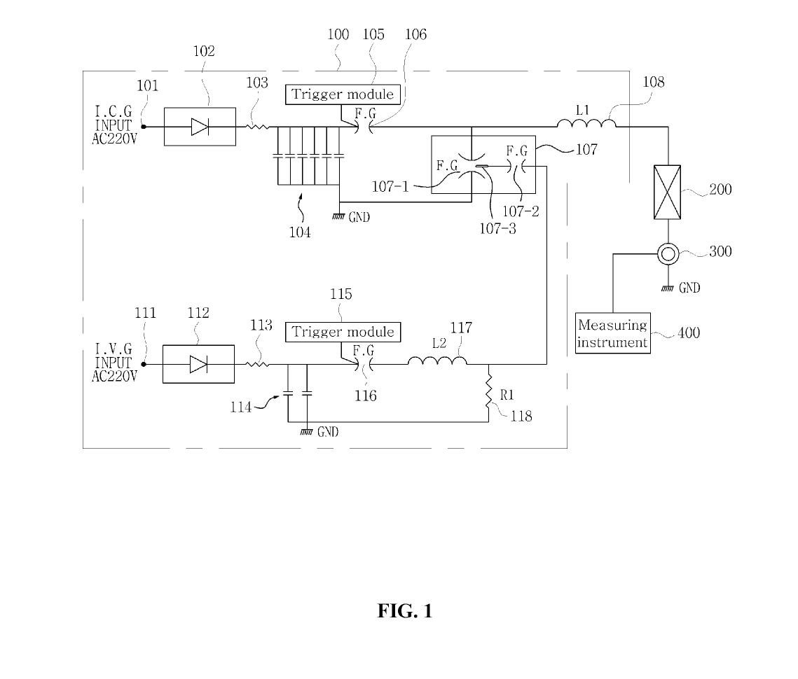

FIG. 1 is a circuit diagram illustrating a ground rod test device for analyzing ground characteristics according to the present invention.

Referring to FIG. 1, the ground rod test device for analyzing ground characteristics includes an impulse generator 100, a test chamber 200, a sensor 300, and a measuring instrument 400.

The impulse generator 100 is an apparatus for generating an impulse waveform, such as an impulse current or impulse voltage waveform of 10/350 μs, and includes an input power source 101 for generating an impulse current and an input power source 111 for generating an impulse voltage. First DC charging means 102 and second DC charging means 112 are connected to one terminal of the input power source 101 for generating an impulse current and the input power source 111 for generating an impulse voltage respectively. Each of the input power source 101 for generating an impulse current and the input power source 111 for generating an impulse voltage uses 220 V AC power.

Each of the first and the second DC charging means 102 and 112 is formed of a diode for rectifying AC into DC. A first charging resistor 103 and a second charging resistor 113 are connected to the first and second DC charging means 102 and 112 in series respectively.

First charging means 104 is connected to the first charging resistor 103, and the other end of the first charging means 104 is connected to a ground GND. The first charging means 104 includes a plurality of capacitors connected in parallel. The first charging means 104 is charged with an input voltage rectified by the first DC charging means 102.

A first trigger module 105 and a first spark gap 106 are connected to the first charging resistor 103 in series. A crowbar switch module 107 is connected to the first charging means 104 and the first spark gap 106 in parallel. The first trigger module 105 generates a trigger signal under the control of control means (not illustrated). The first trigger module 105 sends an electric current to the first spark gap 106 in order to form the wave front part of an impulse current waveform. The first trigger module 105 blocks the electric current transmitted to the first spark gap 106 in order to form the wave tail part of an impulse current waveform under the control of the control means (not illustrated). Furthermore, the first spark gap 106 controls an electric current applied between electrodes by controlling the interval between the electrodes under the control of the control means (not illustrated).

The crowbar switch module 107 includes third and fourth spark gaps 107-1 and 107-2 and a trigger electrode 107-3. The main electrodes of the third spark gap 107-1 may be fabricated to have the same shapes as the upper electrode and lower electrode of the first spark gap 106. The trigger electrode 107-3 capable of conducting the main electrodes is placed between the main electrodes.

A coil L1 108 for controlling the wave tail part is connected to the contact point of the first spark gap 106 and the crowbar switch module 107.

When a trigger signal is generated by the first trigger module 105, the first charging means 104 in a charged state discharges charged voltage. The discharged voltage conducts the electrodes of the first spark gap 106. The waveform of the electric current discharged by the first charging means 104 reaches a peak in about 10 μs after the electric current is discharged, and starts being attenuated after the peak. In such a case, when the current waveform starts being attenuated after reaching the peak, the coil 108 for controlling a wave tail part generates induced electromotive force in a direction along which the attenuation is hindered according to Lenz's law.

A second trigger module 115, a second spark gap 116, and a second coil L2 are connected to the second charging resistor 113 in series. Second charging means 114 and a resistor 118 are connected in parallel. The second trigger module 115 generates a trigger signal under the control of the control means (not illustrated). Furthermore, the second spark gap 116 controls the interval between electrodes under the control of the control means (not illustrated).

The second spark gap 116 may be fabricated to have the same structure as the first spark gap 106. However, the diameter of the electrodes of the second spark gap 116 may be formed to be smaller than that of the electrodes of the first spark gap 106.

The crowbar switch module 107 is connected to the contact point of the second coil L2 117 and the resistor 118. The second coil 117 is electrically connected to the crowbar switch module 107. The second coil 117 and the resistor 118 form an RL circuit, and may control the time constant of an impulse waveform.

The test chamber 200 functions to prevent noise, vibration, and sparks generated due to an impulse waveform (e.g., an impulse current or an impulse voltage) when the impulse waveform is applied to a test load. A ground rod, that is, a test load, is seated in the test chamber 200. The ground rod is electrically connected to the impulse generator 100. The sensor 300 for sensing an impulse waveform output by the ground rod seated in the test chamber 200 is electrically connected to the end of the test chamber 200. The sensor 300 may be a current sensor or a voltage sensor, such as a hall sensor for sensing a current waveform output by the end of the test chamber 200. One end of the sensor 300 is connected to the ground, and the other end thereof is electrically connected to the measuring instrument 400. The measuring instrument 400 measures an impulse waveform (i.e., a voltage or current waveform) sensed by the sensor 300. An oscilloscope may be used as the measuring instrument 400. The measuring instrument 400 is used to analyze the characteristics (conductivity and surge impedance, etc.) of the ground rod, and may be connected to an analysis apparatus.

The operational process of the impulse generator 100 of the ground rod test device is described below with reference to FIG. 1.

First, the first charging means 104 and the second charging means 114 are charged with power sources supplied by the input power source 101 for generating an impulse current and the input power source 111 for generating an impulse voltage respectively.

In response to a trigger signal generated by the first trigger module 105 under the control of the control means (not illustrated), the first charging means 104 discharges charged electric charges, thereby conducting the first spark gap 106 and generating a rising current waveform simultaneously with the discharging. At this time, the control means (not illustrated) may control the interval between the electrodes of the first spark gap 106. The generated current waveform reaches a peak value in 10 μs after the charged electric charges are discharged, and forms the wave front part of an impulse waveform. The generated current waveform starts being attenuated after reaching the peak value.

If the generated current waveform is determined to be a peak value, the control means (not illustrated) blocks the electric current supplied to the first spark gap 106 by controlling the first trigger module 105. Furthermore, the control means (not illustrated) controls the second trigger module 115 so that the second charging means 114 discharges charged electric charges, which conduct the second spark gap 116. The electric current discharged through the second spark gap 116 is applied to the second coil 117 and is input to the fourth spark gap 107-2. The electric current applied to the second spark gap 116 may be controlled in such a manner that described in the first spark gap 106.

The electric current input to the fourth spark gap 107-2 conducts the fourth spark gap 107-2, and is input to the trigger electrode 107-3 of the third spark gap 107-1. The electric current input to the trigger electrode 107-3 and induced electromotive force generated by the coil 108 for controlling a wave tail part conduct the main electrodes of the third spark gap 107-1. Accordingly, a wave tail part of 350 μs may be formed using electrical energy charged in the second spark gap 116 to the fourth spark gap 107-2 and the coil 108 for controlling a wave tail part.

The waveform of the impulse current generated by the impulse generator 100 is applied to the ground rod received in the test chamber 200, and is output through the ground rod. The sensor 300 senses the output waveform output by the ground rod, and the measuring instrument 400 measures the output waveform sensed by the sensor 300.

Characteristics, such as surge impedance of the ground rod, are analyzed based on data measured by the measuring instrument 400.

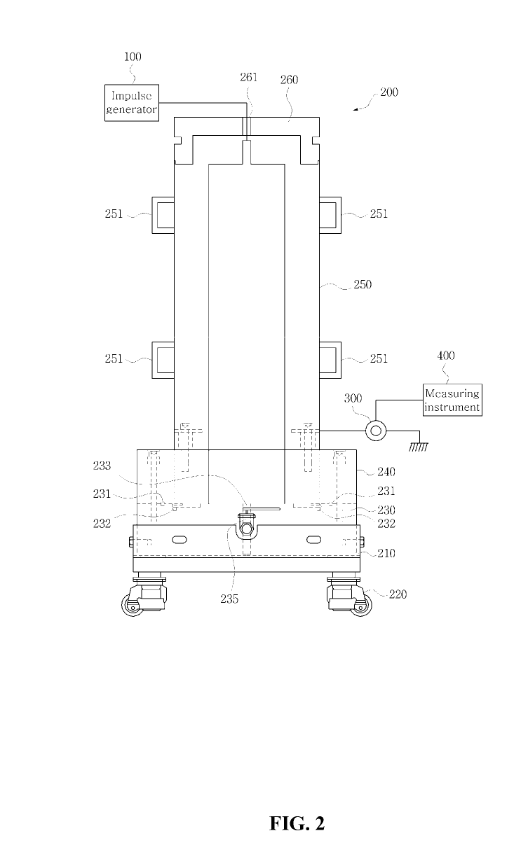

FIG. 2 is a side view illustrating the ground rod test device of FIG. 1.

As illustrated in FIG. 2, the test chamber 200 is an accommodation chamber that accommodates a ground rod 201, that is, a test load, and a conductive liquid. If an impulse waveform is applied to the ground rod 201, the test chamber 200 prevents noise, vibration, and sparks generated due to the impulse waveform.

The ground rod 201, that is, a test load seated in the test chamber 200, is a carbon ground rod. As disclosed in Korean Patent No. 1064342 of the present applicant, the ground rod 201 includes a carbon resistance body extended and formed in a length direction and a conductive core rod installed at the central part of a cross-section area of the carbon resistance body.

The test chamber 200 includes a support unit 210 having the top open and a plurality of casters 220 attached to the edges of the outside lower part of the support unit 210. The caster 220 has a brake function for preventing a movement of a wheel in order to prevent the test chamber 200 from moving due to vibration generated when an impulse waveform is applied to the ground rod 201. The caster having such a brake function may be fabricated to have a structure, such as that disclosed in Korean Patent No. 1003903 (Dec. 17, 2010).

Insertion grooves are formed at the top of the support unit 210, and a lower body 230 is coupled with the insertion grooves. Furthermore, buffer materials are attached to the inside of the support unit 210 in order to prevent shaking attributable to vibration generated when an impulse current is applied to the ground rod 201 by reducing the generated vibration. Rubber, silicon pad, etc. may be used as such buffer materials.

In order to firmly fix the support unit 210 and the lower body 230, the support unit 210 and the lower body 230 are firmly fixed using coupling means, such as bolts, at the outside wall of the support unit 210.

First gasket insertion grooves 231 and second gasket insertion grooves 232 are formed in the upper surface of the lower body 230. An outlet 233 is downwardly formed at the center in such a way as to penetrate the outside wall. A valve 235 is installed at the outlet 233. The valve 235 may be formed of a ball valve.

First gaskets for preventing a conductive liquid from leaking upon combination with the upper body 240 are inserted into the first gasket insertion grooves 231. Second gaskets for preventing the leakage of a conductive liquid accommodated in the pipe 250 upon combination with a pipe 250 are inserted into the second gasket insertion grooves 232. The second gasket is formed along the lower circumference of the pipe 250, and also functions to support the pipe 250.

An upper body 240 is combined with the top of the lower body 230 by coupling means. A through hole configured to penetrate the upper body 240 up and down is formed in the upper body 240. The lower body 230 and the upper body 240 may be formed in one body.

The pipe 250 is inserted into and installed in the through hole of the upper body 240. The upper body 240 and the pipe 250 are firmly fixed by coupling means. The pipe 250 is formed in a pillar shape, and includes a space for accommodating the ground rod 201 and a conductive liquid (e.g., water). In this case, a conductive gas may be used instead of the conductive liquid. If the conductive gas is used, a gas injection chamber, an exhaust pump, etc. are additionally installed in the test chamber 200. Furthermore, the pipe 250 is made of metal, and the outer wall of the pipe 250 is covered with insulating coating.

A terminal formed in the outer wall of the pipe 250 is electrically connected to the sensor 300. One end of the sensor 300 is connected to the ground, and the other end thereof is connected to the measuring instrument 400.

A plurality of handles 251 is protruded on the outer wall of the pipe 250, and each has a cross section of ‘D’ shape.

A finishing unit 260 that closes the open top of the pipe 250 is installed at the top of the pipe 250. The finishing unit 260 is formed in a doughnut form. An electric wire is input through a hole at the center of the finishing unit 260 and is connected to one end of the ground rod 201. That is, the ground rod 201 is electrically connected to the impulse generator 100. Part of the bottom of the finishing unit 260 is inserted into and combined with the open top of the pipe 250.

The lower body 230, the upper body 240, and the pipe 250 are combined by coupling means, and the ground rod 201 is seated in an accommodation space formed by the combination. After the ground rod 201 is seated in the accommodation space of the test chamber 200, the remaining space of the accommodation space is filled with a conductive liquid. In this case, part of the upper part of the ground rod 201 should not be immersed into the conductive liquid. Thereafter, when the impulse generator 100 is driven to apply an impulse waveform to the ground rod 201, the ground rod 201 lets the impulse waveform flow. An output waveform output by the ground rod 201 is transferred to the inner wall of the pipe 250 through the medium of the conductive liquid. The output waveform transferred to the inner wall of the pipe 250 is transferred to the sensor 300 through the terminal formed in the outer wall of the pipe 250. The measuring instrument 400 measures the output waveform sensed by the sensor 300. Furthermore, the characteristics of the ground rod 201 are analyzed based on data measured by the measuring instrument 400.

1. A ground rod test device for analyzing ground characteristics, including:
an impulse generator that generates an impulse waveform;
a test chamber that accommodates a ground rod to which the impulse waveform is applied and a conductive fluid;
a sensor that senses the impulse waveform output by the ground rod; and
a measuring instrument that measures the impulse waveform sensed by the sensor.

2. The ground rod test device of claim 1, wherein the impulse generator comprises:
first DC charging means electrically connected to an input power source for generating an impulse current;
a first spark gap electrically connected between the first DC charging means and the ground rod of the test chamber and operating in response to a trigger signal output by a first trigger module;
a coil electrically connected between the first spark gap and a test load and controlling a wave tail part of the impulse waveform;
second DC charging means electrically connected to an input power source for generating an impulse voltage;
a second spark gap electrically connected between the second DC charging means and a crowbar switch module and operating in response to a trigger signal generated by a second trigger module;
second charging means electrically connected between the second DC charging means and the second spark gap;
a time constant control circuit electrically connected between the second spark gap and the crowbar switch module and controlling a time constant of the impulse waveform; and
a control means that controls the first and the second trigger modules and the first and the second spark gaps so that the wave tail and wave front parts of the impulse waveform are formed.

3. The ground rod test device of claim 1, wherein the test chamber comprises:
a support unit having a top open and a plurality of casters installed at edges of a bottom of the support unit;
a lower body inserted into and coupled to the top of the support unit, wherein first and second insertion grooves and an outlet that downwardly penetrates the lower body toward an outside wall from the center of a top surface of the lower body are formed at the top surface of the lower body;
an upper body coupled with a top of the lower body by coupling means, wherein a through hole that penetrates the upper body up and down is formed at a center of the upper body;
a pipe formed in a pillar shape and inserted into and coupled with the through hole; and
a finishing unit that closes a top of the pipe, wherein a hole is formed at a center of the finishing unit,
wherein the ground rod is seated in an accommodation space formed by the coupling of the lower body, the upper body, and the pipe, and the accommodation space is filled with the conductive fluid.

4. The ground rod test device of claim 3, wherein an outer circumferential surface of the pipe is surrounded by insulating coating.

5. The ground rod test device of claim 3, further comprising a valve installed in the outlet in order to externally discharge the conductive fluid of the accommodation space.

6. The ground rod test device of claim 3, wherein gaskets for preventing the conductive fluid from leaking are inserted into and installed at the first and the second insertion grooves.

7. The ground rod test device of claim 3, wherein buffer materials for reducing vibration generated when the impulse current is applied to the ground rod are attached to an inner surface of the support unit.
